(19) United States
(12) Patent Application Publication
(10) Pub. No.: US 2022/0415762 A1
(43) Pub. Date: Dec. 29, 2022

(54) SEMICONDUCTOR PACKAGE WITH DRILLED MOLD CAVITY

(71) Applicant: TEXAS INSTRUMENTS INCORPORATED, Dallas, TX (US)

(72) Inventors: Christopher Daniel Manack, Flower Mound, TX (US); Jonathan Andrew Montoya, Dallas, TX (US); Steven Alfred Kummerl, Carrollton, TX (US); Salvatore Frank Pavone, Murphy, TX (US)

(21) Appl. No.: 17/359,635

(22) Filed: Jun. 27, 2021

(51) Int. Cl. H01L 23/495; H01L 23/498; H01L 23/31; H01L 23/60; H01L 21/56

(52) U.S. Cl. CPC H01L 23/49541; H01L 23/49861; H01L 23/31; H01L 23/60; H01L 21/56

(57) ABSTRACT

A semiconductor package includes a semiconductor die including terminals, a plurality of leads, at least some of the leads being electrically coupled to the terminals within the semiconductor package, a sensor on a surface of the semiconductor die, laser shielding forming a perimeter around the sensor on the surface of the semiconductor die, and a mold compound surrounding the semiconductor die except for an area inside the perimeter on the surface of the semiconductor die such that the sensor is exposed to an external environment.

### TECHNICAL FIELD

This disclosure relates to semiconductor packages.

### BACKGROUND

Electronic package technology continues trends towards miniaturization, integration, and speed. Semiconductor packages provide support for a semiconductor die, such as an integrated circuit (IC) chip, and associated bond wires, provide protection from the environment, and enable surface-mounting of the die to and interconnection with an external component, such as a printed circuit board (PCB). Leadframe semiconductor packages are well known and widely used in the electronics industry to house, mount, and interconnect a variety of ICs.

A conventional leadframe is typically die-stamped from a sheet of flat-stock metal and includes a plurality of metal leads temporarily held together in a planar arrangement about a central region during package manufacture by siderails forming a rectangular frame. A mounting pad for a semiconductor die is supported in the central region by “tie-bars” that attach to the frame. The leads extend from a first end integral with the frame to an opposite second end adjacent to, but spaced apart from, the die pad. As alternatives to a conventional leadframe, routable leadframes include at least one metal layer supported by a dielectric layers, such as laminate films and/or premolded dielectric layers.

In a semiconductor sensor package, a semiconductor die includes a sensor adapted to sense a physical parameter of an external environment surrounding the semiconductor sensor package. For example, in a capacitive-type humidity sensor a thin polymer film is attached to a surface of a semiconductor die and is connected to electrical circuitry within the die. Changes in humidity affect the amount of moisture absorbed by the polymer film. Moisture absorption causes a change in the capacitance of the film. This change in capacitance is measured by the die circuitry and is representative of the humidity of the air. To make such a semiconductor sensor package, the polymer film attached to the die must be exposed to the surrounding air.

### BRIEF SUMMARY

Packages disclosed herein include a drilled mold cavity exposing a portion of a semiconductor die covered by package mold compound. Packages may be manufactured by first molding over a semiconductor die with a laser shielding, laser drilling through mold compound to create a drilled mold cavity and then chemically etching the laser shielding to expose the semiconductor die. As a result of such manufacturing processes, packages disclosed herein include a perimeter of the laser shielding on the semiconductor die that surrounds the mold cavity and laser drill marks on the surface of cavity walls. The techniques disclosed herein may be incorporated into semiconductor sensor packages to expose a sensor on the semiconductor die to the external environment. Such techniques may facilitate reductions in package size compared to using mechanical blocks to create mold cavities for die sensors during package molding.

In one example, a semiconductor package includes a semiconductor die including terminals, a plurality of leads, at least some of the leads being electrically coupled to the terminals within the semiconductor package, a sensor on a surface of the semiconductor die, laser shielding forming a perimeter around the sensor on the surface of the semiconductor die, and a mold compound surrounding the semiconductor die except for an area inside the perimeter on the surface of the semiconductor die such that the sensor is exposed to an external environment.

In a further example, a method of forming a package includes covering a sensor on a surface of the semiconductor die with laser shielding, electrically coupling terminals of the semiconductor die to a plurality of leads, molding a mold compound over the semiconductor die, laser drilling the mold compound to expose at least a portion of the laser shielding covering the sensor, and etching the laser shielding to expose the sensor to an external environment.

### BRIEF DESCRIPTION OF THE DRAWINGS

FIGS. 1A-1C illustrate a semiconductor package including laser shielding forming a perimeter around a sensor on the surface of a semiconductor die.

FIGS. 2A-2H illustrate conceptual process steps for manufacturing the package of FIGS. 1A-1C.

FIG. 3 is flowchart of a method of manufacturing a semiconductor package by first molding over a semiconductor die with laser shielding, laser drilling through mold compound to create a drilled mold cavity and then chemically etching the laser shielding to expose a portion of the semiconductor die to an external environment.

### DETAILED DESCRIPTION

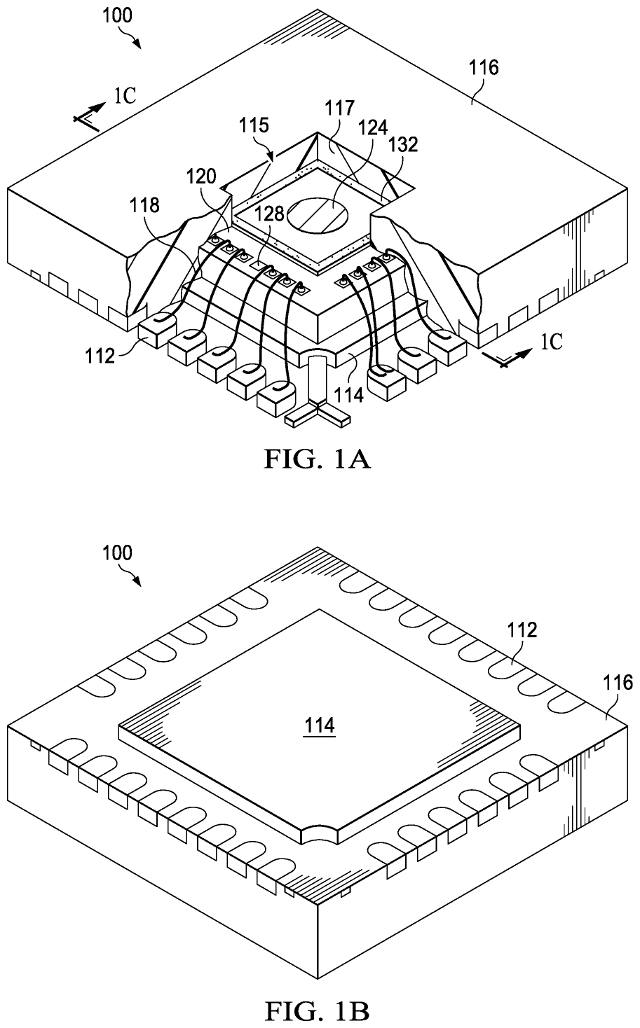

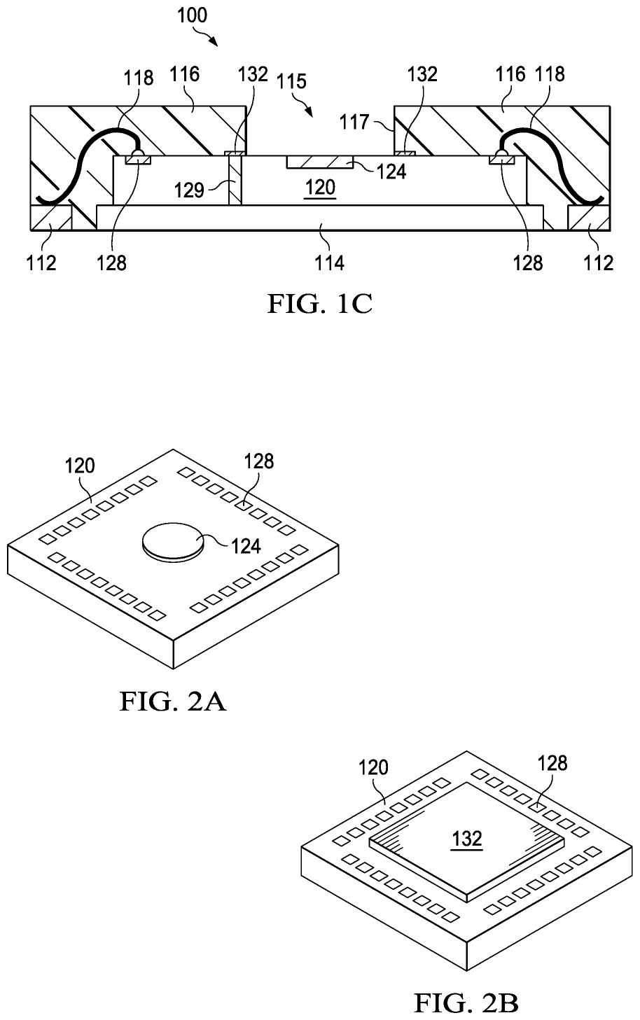

FIGS. 1A and 1B illustrate semiconductor package 100. Specifically, FIG. 1A illustrates a top perspective partial cutaway view of semiconductor package 100, FIG. 1B illustrates a bottom perspective view of semiconductor package 100, and FIG. 1C illustrates a cross-sectional view of semiconductor package 100. Semiconductor package 100 includes a semiconductor die 120 with a sensor 124 exposed in a mold cavity 115 of mold compound 116. In various examples, sensor 124 may include any sensor involving a measurement of the external environment, such as a pressure sensor, a humidity sensor, a light sensor, a dewpoint sensor, and/or an electrochemical sensor.

Package 100 is a QFN package including a leadframe with leads 112 and a die attach pad 114, which also serves as a thermal pad to facilitate heat dissipation of package 100. In at least one example, the leadframe is constructed of copper material, 200 μm (or 8 mils) thick and the width of each lead is 250 μm. Semiconductor die 120 is attached, via a die attach material (not shown), to a top surface of die attach pad 114. In the example package 100, wire bonds 118 extend between leads 112 and the bond pads or terminals 128 of semiconductor die 120, electrically coupling terminals 128 to associated leads 112. Gold, copper, or palladium coated wire are examples of wire that may be used for wire bonds 118. Mold compound 116 covers the assembly of semiconductor die 120, die attach pad 114 and wire bonds 118. Typically, plastic is used as the mold compound, but use of other materials, including ceramics, can also be used.

The exposed surface of the die attach pad 114 can be soldered to a corresponding pad on a wiring substrate, such as a printed wiring board (PWB) or printed circuit board (PCB), or attached with other heat conductive die attach material. Leads 112 of QFN package 100 can be soldered to corresponding electrical contacts or terminals, on a PWB.

Semiconductor die 120 comprises a substrate (e.g., silicon or silicon/germanium) having an active surface and an inactive surface. Die terminals 128 and sensor 124 are exposed in bond pad openings in a dielectric layer of semiconductor die 120 on its active surface. Die terminals 128 are bonded to a metallization layer including functional circuitry (not shown) in a semiconductor substrate beneath an outer dielectric layer. Elements of sensor 124 are formed by functional circuitry and elements exposed in openings in the dielectric layer of semiconductor die 120 on its active surface. Semiconductor die 120 includes terminals 128 and a sensor 124 on the same side of semiconductor die 120, i.e., on the active surface of semiconductor die 120. The opposite surface, the inactive surface, of semiconductor die 120 is bonded to die attach pad 114.

The functional circuitry of semiconductor die 120 is formed on a semiconductor wafer prior to singulation of semiconductor die 120 and includes circuit elements forming sensor 124, such as transistors, diodes, capacitors, and resistors, as well as signal lines and other electrical conductors that interconnect the various circuit elements. As nonlimiting examples, such functional circuitry may include an application specific integrated circuit (ASIC), a digital signal processor, a radio frequency chip, a memory, a microcontroller and a system-on-a-chip or a combination thereof. The functional circuitry is generally integrated circuitry that realizes and carries out desired functionality of the package, such as that of a sensor 124, which may include a digital IC (e.g., digital signal processor) or analog IC (e.g., amplifier or power converter), such as a BiMOS IC. The capability of functional circuitry may vary, ranging from a simple device to a complex device.

Mold compound 116 provides a protective layer covering electronics of semiconductor package 100, including semiconductor die 120 and wire bonds 118. Mold compound 116 may be formed from a nonconductive plastic or resin material. Suitable mold compounds include, for example, thermoset compounds that include an epoxy novolac resin or similar material combined with a filler, such as alumina, and other materials to make the compound suitable for molding, such as accelerators, curing agents, filters, and mold release agents. Mold compound 116 forms a mold cavity 115, which exposes a portion of the active surface of semiconductor die 120 that includes sensor 124 to the external environment.

As disclosed herein, mold cavity 115 may be formed by laser drilling mold compound 116 over sensor 124. Laser shielding 132, which functions to protect semiconductor die 120 and sensor 124 from the laser drill. Following the laser drilling to form mold cavity 115, laser shielding 132 over sensor 124 is removed such that sensor 124 is exposed to the external environment. A portion of laser shielding 132 remains within the manufactured package 100. This portion of laser shielding 132 forms a perimeter around the sensor 124 on the active surface of the semiconductor die 120. For example, laser shielding 132 is oversized compared to mold cavity 115, which ensures that semiconductor die 120 is protected during the laser drilling. A portion of the laser shielding 132 is exposed to the external environment and forms a contiguous surface with the surface 117 of mold compound 116 about the perimeter around the sensor 124 on the active surface of the semiconductor die 120. Mold cavity 115 is inside the perimeter of laser shielding 132 on the surface of the semiconductor die 120 such that the sensor 124 is exposed to the external environment.

In some examples, laser shielding 132 is a metal alloy, such as a metal alloy predominantly including copper, titanium, titanium-tungsten, gold, platinum, iron, aluminum, or silver. As referred to herein, predominantly including means at least 50 percent by weight, up to 100 percent by weight. In a specific example, the laser shielding 132 is a metal, such as a metal predominately including copper, with a thickness in a range of 1000 Angstrom (A) to 10,000 A. In other examples, laser shielding 132 may be formed by a non-metal, such as silicon oxide or silicon nitride.

The dimensions of laser shielding 132 may be selected according to the particular requirements of semiconductor die 120 and sensor 124. The size and shape of laser shielding 132 is selected exceed the perimeter of mold cavity 115 around sensor 124. In some examples, the width and length of the outer perimeter of laser shielding 132 is over 50 microns, such as 50-1000 microns. While laser shielding 132 is depicted as a square, any shape forming a perimeter around sensor 124 may be selected for laser shielding 132. Possible shapes for the perimeter around sensor 124 on the surface of semiconductor die 120 include circles, ovals, triangles, squares, rectangles, trapezoids, or other polygons.

Laser shielding 132 is optionally coupled to a grounded electrical potential by way of attachment to a metallization layer of semiconductor die 120, or by way of a through semiconductor via 129 connection to die attach pad 114. Such a grounded connection to laser shielding 132 may provide electrical shielding of sensor 124 during operation of package 100. Such shielding may mitigate electrical interference of sensor 124, improving the consistency or accuracy of sensor 124.

Surface 117 forms sidewalls of mold cavity 115, adjacent the area inside the perimeter about sensor 124 on the active surface of the semiconductor die 120. As a result of the laser drilling manufacturing process, surface 117 includes laser drill marks. The laser drill marks are elongated surface imperfections generally aligned with the orientation of the laser during manufacturing, e.g., aligned the thickness of mold compound 116 above semiconductor die 120. The size of the surface imperfections will be dependent on the laser drilling parameters, such as wavelength, pulse width, pulse energy, pulse duration, assist gas flow rate, focal length, speed, etc., as well as the material of mold compound 116.

Mold cavity 115 may have a length and a width within a range of 50 microns to 1000 microns, and the outer profile of laser shielding 132 may have a length and a width that exceeds the length and width of mold cavity by 10 to 500 microns. The outer profile of laser shielding 132 should be spaced from die terminals 128 to mitigate shorting. Laser drilling techniques also facilitate any shape for the profile of mold cavity 115 including, but not limited, to circles, ovals, triangles, squares, rectangles, trapezoids, or other polygons. Laser drilling facilitates mold cavities to access sensors, such as mold cavity 115, that are much smaller than mold cavities to access sensors manufactured with mechanical inserts to block mold flow.

Due to high stresses during molding, mechanical inserts provide mold cavities with a minimum width of about 0.5 millimeters (500 microns). Most mechanical inserts are spring loaded and require high precision manufacturing in the sub-millimeter range of package features. During batch molding processes, high density of such mechanical inserts creates manufacturing challenges due to weakening the overall mold tooling. For example, molding processes may use more than a ton of hydraulic pressure. In contrast, laser drilling mold cavity 115 of semiconductor package 100 after molding eliminates the need for mechanical inserts. With laser drilling as disclosed herein the mold tooling can utilize a planar surface without mechanical inserts for batch molding an array of semiconductor packages within a leadframe strip.

Semiconductor package 100 is manufactured using two complex manufacturing processes, i.e., front-end manufacturing and back-end manufacturing, each involving potentially hundreds of steps. Front-end manufacturing involves the formation of a plurality of semiconductor dies 120 on the surface of a semiconductor wafer. Each die is typically identical and contains circuits formed by electrically connecting active and passive components. Back-end manufacturing involves singulating individual semiconductor dies 120 from the finished wafer and packaging the die to provide structural support and environmental isolation. Laser shielding 132 may be added either as part of the front-end manufacturing or the back-end manufacturing.

Conventional leadframes, including leads 112 and die attach pads 114 for an array of packages 100 are formed on a single, thin sheet of metal as by stamping or etching. Multiple interconnected leadframes may be formed on a single leadframe sheet, the interconnected leadframes referred to as a leadframe strip. Leadframes on the sheet can be arranged in rows and columns. Tie bars connect leads and other elements of a leadframe to one another as well as to elements of adjacent leadframes in a leadframe strip. A siderail may surround the array of leadframes to provide rigidity and support leadframe elements on the perimeter of the leadframe strip. The siderail may also include alignment features to aid in manufacturing.

Usually die mounting, die to leadframe attachment, such as solder reflowing, wire bonding or metal trace pattering, and molding to cover at least part of the leadframe and dies take place while the leadframes are still integrally connected as a leadframe strip. After such processes are completed, the leadframes, and sometimes mold compound of a package, are severed (“singulated” or “diced”) with a cutting tool, such as a saw or laser. These singulation cuts separate the leadframe strip into separate IC packages, each IC package including a singulated leadframe, at least one die, electrical connections between the die and leadframe (such as gold or copper bond wires) and the mold compound which covers at least part of these structures.

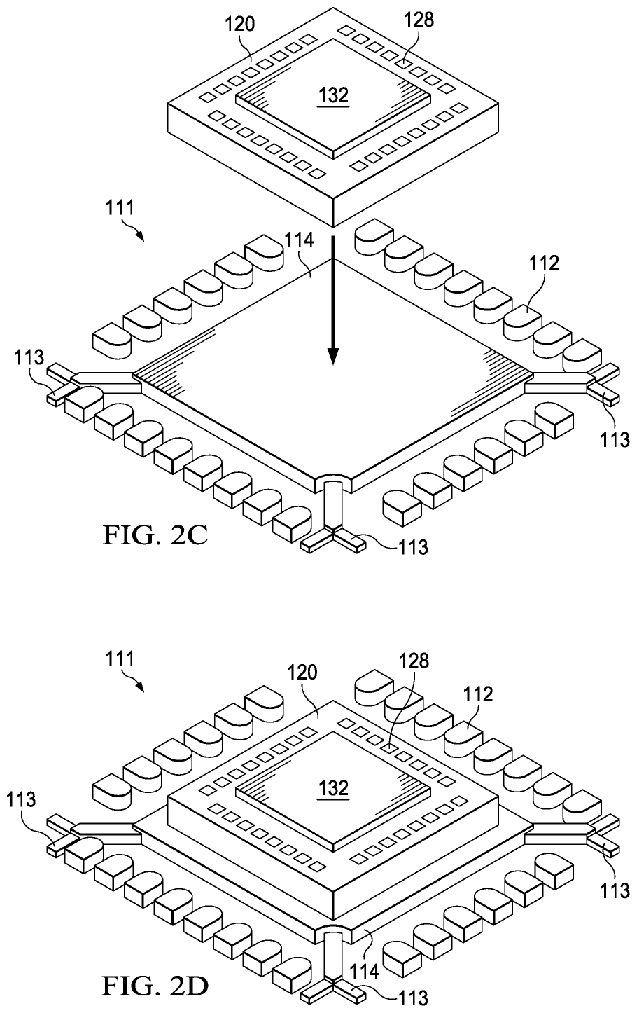

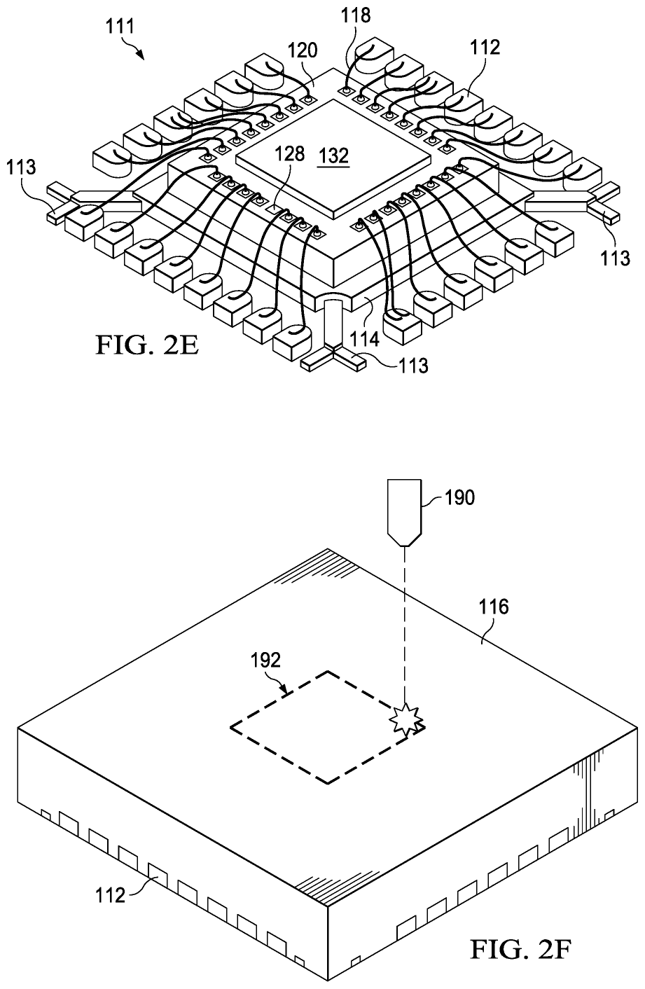

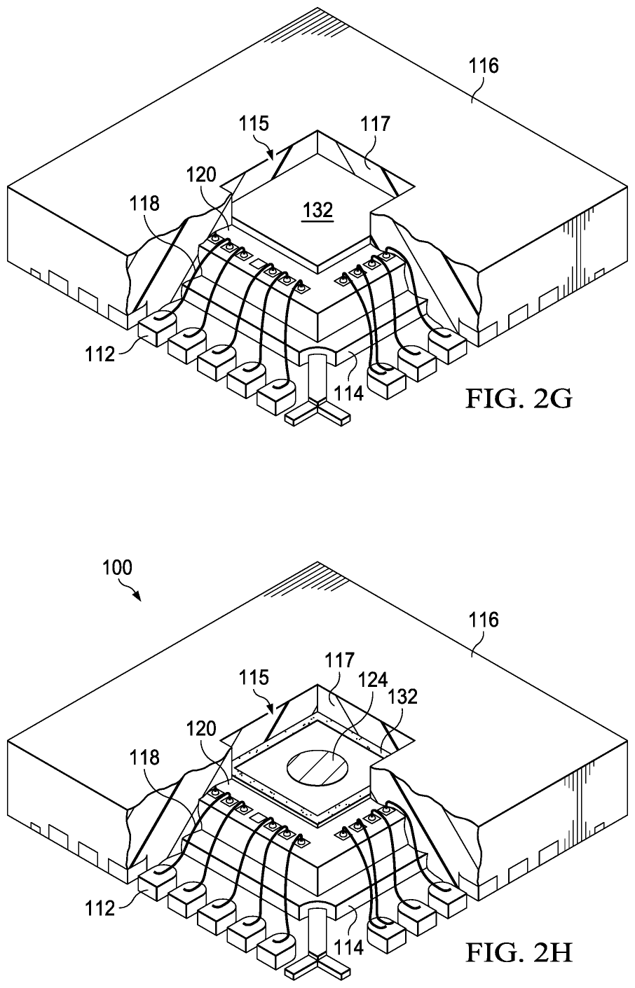

Tie bars and siderails may be removed during singulation of the packages. The term leadframe of represents the portions of the leadframe strip remaining within a package after singulation. With respect to semiconductor package 100, the leadframe includes leads 112, a portion of tie bars 113, and die attach pad 114, although those conductive elements are not directly interconnected following singulation of semiconductor package 100. Further details regarding the structure and function of semiconductor package 100 provided in FIGS. 2A-2H and the corresponding description.

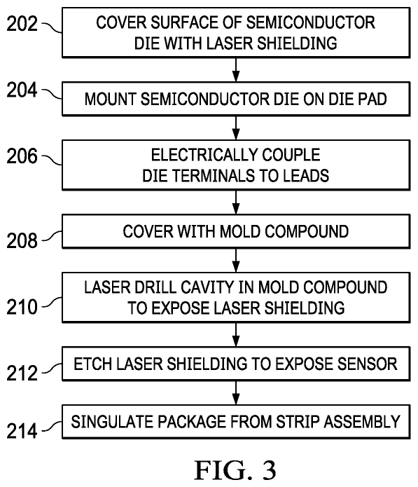

FIGS. 2A-2H illustrate conceptual process steps for manufacturing semiconductor package 100. FIG. 3 is flowchart of a method of manufacturing a semiconductor package including laser shielding forming a perimeter around a sensor on the surface of a semiconductor die, such as semiconductor package 100. For clarity, the techniques of FIG. 3 are described with respect to semiconductor package 100 and FIGS. 2A-2H; however, the described techniques may also be readily adapted to alternative package configurations.

FIG. 2A illustrates a perspective view of semiconductor die 120. Semiconductor die 120 includes an active surface with sensor 124 and terminals 128. Terminals 128 extend through an outer dielectric layer of semiconductor die 120 and are electrically connected to the circuit elements formed within semiconductor die 120. Terminals 128 include one or more layers of conductive material, such as a such as a metal predominately including aluminum, copper, tin, nickel, gold, or silver.

As shown in FIG. 2B, sensor 124 is covered with laser shielding 132 on the active surface of semiconductor die 120 (FIG. 3, step 202). For example, covering sensor 124 with laser shielding 132 may include electroplating laser shielding 132 on the active surface of semiconductor die 120. Depending on the materials used for laser shielding 132, covering sensor 124 with laser shielding 132 may including deposition and/or printing. While semiconductor die 120 is depicted in FIGS. 2A and 2B as a singulated semiconductor die 120, covering sensor 124 with laser shielding 132 may occur either prior to or after singulation of semiconductor die 120 from the semiconductor wafer. In some examples, covering sensor 124 with laser shielding 132 may occur after mounting semiconductor die 120 to die attach pad 114.

As shown in FIGS. 2C-2D, a singulated semiconductor die 120 including laser shielding 132, is mounted on die attach pad 114 with the active surface including sensor 124 facing outward, opposite die attach pad 114 (FIG. 3, step 204). For example, a die attach paste may be used to secure semiconductor die 120 to die attach pad 114.

As represented by FIG. 2E, terminals 128 of semiconductor die 120 are electrically coupled to a plurality of leads 112 with wire bonds 118 (FIG. 3, step 206). In addition, laser shielding 132 is optionally electrically coupled to a grounded electrical potential by way of attachment to a metallization layer of semiconductor die 120, or by way of a through semiconductor via 129 (FIG. 1C) connection to die attach pad 114.

As represented by FIG. 2F, mold compound 116 is deposited on the assembled device of FIG. 2E, covering semiconductor die 120, wire bonds 118, and laser shielding 132, and partially covering leads 112 and die attach pad 114 (FIG. 3, step 208). For example, mold compound 116 may be applied by paste printing, compressive molding, transfer molding, liquid encapsulant molding, vacuum lamination, spin coating, or other suitable technique.

As further represented FIGS. 2F and 2G, mold cavity 115 is formed by laser drilling the mold compound 116 with laser drill 190 within area 192, thereby exposing a portion of the laser shielding 132 covering the sensor 124 within area 192 (FIG. 3, step 210).

As shown in FIG. 2G, following the formation of mold cavity 115 with laser drill 190, laser shielding 132 is intact on the active surface of semiconductor die 120, such that it still covers sensor 124. As represented by FIG. 2H, laser shielding 132 removed from mold cavity 115 by etching to expose sensor 124 to the external environment (FIG. 3, step 212). In examples where laser shielding 132 is a metal alloy predominantly including copper, etching may include chemically etching the laser shielding 132 with an etchant including ferric chloride.

Etching laser shielding 132 to expose sensor 124 to the external environment leaves a portion of laser shielding 132 forming a perimeter around the sensor 124 on the active surface of semiconductor die 120. In some examples, the portion of laser shielding 132 forming a perimeter around the sensor 124 on the active surface of semiconductor die 120 has a width in the range of 10-500 microns. Mold compound 116 protects this portion of laser shielding 132 during the etching process.

Following the etching of laser shielding 132, sensor 124 is exposed to the external environment within mold cavity 115. The dimensions of mold cavity 115 may be selected according to the particular requirements of semiconductor die 120 and sensor 124. In some examples, the width and length of mold cavity 115 is over 100 microns, such as a length of 100-1000 microns. While mold cavity 115 is depicted as a square, any shape forming a perimeter around sensor 124 may be selected. Possible shapes for mold cavity 115 the surface of semiconductor die 120 include circles, ovals, triangles, squares, rectangles, trapezoids, or other polygons. In the same or different examples, mold cavity 115 may have a height of at least 50 microns, such as a height of 50-1000 microns. The height of mold cavity 115 should be sufficient to facilitate mold flow over the active surface of semiconductor die 120.

In some examples, semiconductor package 100 may be one of an array of packages manufactured on an array of interconnected leadframes and molded in a batch process. In such examples, the method further includes singulating the array of molded packages to form individual semiconductor packages 100 (FIG. 3, step 214). Singulation may include cutting through leads 112, mold compound 116 and tie bars 113 (FIG. 2E) linking the interconnected leadframes with a saw or other cutting implement. The siderail and portions of tie bars 113 are removed during singulation. As package 100 is a leadless package, following singulation, the exposed end surfaces of leads 112 are coplanar with an outer side surface of mold compound 116. However, the specific package configuration is not germane to this disclosure, the applied techniques may be used in packages with any lead configuration, such as gull-wing packages, “J” leaded packages, and “I” leaded packages.

The specific techniques for semiconductor packages including laser shielding forming a perimeter around a sensor on the surface of a semiconductor die, including techniques described with respect to semiconductor package 100, are merely illustrative of the general inventive concepts included in this disclosure as defined by the following claims.

What is claimed is:

1. A semiconductor package, comprising:
a semiconductor die including terminals,
a plurality of leads, at least some of the leads being electrically coupled to the terminals within the semiconductor package;
a sensor on a surface of the semiconductor die;
laser shielding forming a perimeter around the sensor on the surface of the semiconductor die; and
a mold compound surrounding the semiconductor die except for an area inside the perimeter on the surface of the semiconductor die such that the sensor is exposed to an external environment.

2. The semiconductor package of claim 1, wherein the surface of the mold compound adjacent the area inside the perimeter include laser drill marks.

3. The semiconductor package of claim 1, wherein the laser shielding is coupled to a ground potential.

4. The semiconductor package of claim 1, wherein the laser shielding is a metal predominantly including one of a group consisting of:
copper;
titanium;
titanium-tungsten;
gold;
platinum;
iron;
aluminum; and
silver.

5. The semiconductor package of claim 1, wherein the laser shielding is a metal alloy predominantly including copper with a thickness in a range of 1000 Angstrom (A) to 10,000 A.

6. The semiconductor package of claim 1, wherein a portion of the laser shielding is exposed to the external environment and forms a contiguous surface with the mold compound about the perimeter around the sensor.

7. The semiconductor package of claim 1, wherein the terminals are on the same side of the semiconductor die as the sensor.

8. The semiconductor package of claim 1, further comprising wire bonds extending from the terminals, wherein the wire bonds are in electrical contact with the plurality of leads.

9. The semiconductor package of claim 1, wherein the sensor includes one or more of a group consisting of:
a pressure sensor;
a humidity sensor;
a light sensor;
a dewpoint sensor; and
an electrochemical sensor.

10. The semiconductor package of claim 1, wherein the semiconductor package is a leadless package.

11. A method of forming a semiconductor package comprising:
covering a sensor on a surface of the semiconductor die with laser shielding;
electrically coupling terminals of the semiconductor die to a plurality of leads;
molding a mold compound over the semiconductor die;
laser drilling the mold compound to expose at least a portion of the laser shielding covering the sensor; and
etching the laser shielding to expose the sensor to an external environment.

12. The method of claim 11, wherein etching the laser shielding to expose the sensor to the external environment leaves a portion of the laser shielding forming a perimeter around the sensor on the surface of the semiconductor die.

13. The method of claim 11, further comprising coupling the laser shielding to a ground potential.

14. The method of claim 11, wherein the laser shielding is a metal alloy, the method further comprising electroplating the laser shielding on the surface of the semiconductor die.

15. The method of claim 11, wherein the laser shielding is a metal predominantly including one of a group consisting of:
copper;
titanium;
titanium-tungsten;
gold;
platinum;
iron;
aluminum; and
silver.

16. The method of claim 11,
wherein the laser shielding is a metal predominantly including copper, and
wherein the etching including chemically etching the laser shielding with an etchant including ferric chloride.

17. The method of claim 11, wherein electrically coupling the terminals of the semiconductor die to the plurality of leads includes wire bonding the terminals of the semiconductor die to the plurality of leads.

18. The method of claim 11, further comprising mounting the semiconductor die with the laser shielding on the surface of the semiconductor die on a die pad with the laser shielding opposite the die pad.

19. The method of claim 11, further comprising, after molding the mold compound over the semiconductor die, singulating the semiconductor package from a strip of semiconductor packages molded in a batch process.

20. The method of claim 11, wherein the semiconductor package is a leadless package.
